(19) United States
(12) Patent Application Publication
(10) Pub. No.: US 2013/0162359 A1
(43) Pub. Date: Jun. 27, 2013

(54) FREQUENCY JITTER CIRCUIT AND METHOD

(71) Applicant: RICHTEK TECHNOLOGY CORP., Hsinchu City (TW)

(72) Inventors: CHIEN-FU TANG, Hsinchu City (TW); ISAAC Y. CHEN, Hsinchu County (TW)

(73) Assignee: RICHTEK TECHNOLOGY CORP., Hsinchu City (TW)

(21) Appl. No.: 13/772,628

(22) Filed: Feb. 21, 2013

Related U.S. Application Data
(62) Division of application No. 13/221,011, filed on Aug. 30, 2011.

(30) Foreign Application Priority Data
Sep. 2, 2010 (TW) 099129716

(51) Int. Cl. H03B 29/00

(52) U.S. Cl. CPC H03B 29/00
USPC 331/78

(57) ABSTRACT

An oscillator generates a clock signal according to a voltage, a current and a capacitance, and a frequency jitter circuit and method use a random number to modulate the voltage, the current or the capacitance, or a count value to modulate the capacitance, to jitter the frequency of the clock signal.

### RELATED APPLICATIONS

This application is a Divisional patent application of co-pending application Ser. No. 13/221,011, filed on 30 Aug. 2011, now pending. The entire disclosure of the prior application, Ser. No. 13/221,011, from which an oath or declaration is supplied, is considered a part of the disclosure of the accompanying Divisional application and is hereby incorporated by reference.

### FIELD OF THE INVENTION

The present invention is related generally to a frequency jitter circuit and method and, more particularly, to frequency jitter control of a clock signal.

### BACKGROUND OF THE INVENTION

In the field of switching alternating current/direct current (AC/DC) power converters, electro-magnetic interference (EMI) is a major issue in system design. There are several approaches for EMI solution. In general, spread spectrum is a popular one. For example, U.S. Pat. No. 6,249,876 proposed jittering the switching frequency of a switched mode power supply by counter and current digital-to-analog converter (DAC) that is frequently used in AC/DC flyback products. In further details, this art varies the switching frequency of an oscillator that is controlled to generate a jittered clock signal by connecting the oscillator to a counter clocked by the oscillator to control at least two current sources within a current DAC that provide a variable current to the control input of the oscillator for varying the oscillator's switching frequency. Similarly, U.S. Pat. No. 6,847,257 feeds back the output clock signal of an oscillator for jittering the frequency of the clock signal. Further, this art is limited to applications of class-D amplifiers. U.S. Pat. No. 7,289,582 also feeds back the output clock signal of an oscillator to a counter that controls a variable voltage provided to the oscillator for jittering the frequency of the clock signal.

### SUMMARY OF THE INVENTION

An objective of the present invention is to provide a frequency jitter circuit and method.

Another objective of the present invention is to provide a frequency jitter circuit and method implemented by a smaller circuit.

A further objective of the present invention is to provide a frequency jitter circuit and method implemented by a simpler circuit.

In an embodiment according to the present invention, a frequency jitter circuit includes an oscillator to generate a clock signal according to the capacitance of a capacitor, a voltage provided by a voltage source, and a current provided by a current source, and a random number generator to provide a random number to modulate the current for jittering the frequency of the clock signal. This frequency jitter circuit does not need any counter to vary the current responsive to the clock signal or any second current source to provide the current having a varying value.

In another embodiment according to the present invention, a frequency jitter circuit includes an oscillator to generate a clock signal according to the capacitance of a capacitor, a voltage provided by a voltage source, and a current provided by a current source, and a random number generator to provide a random number to modulate the voltage for jittering the frequency of the clock signal. This frequency jitter circuit does not need any counter to vary the voltage responsive to the clock signal or any second voltage source to provide the voltage having a varying value.

In yet another embodiment according to the present invention, a frequency jitter circuit includes an oscillator to generate a clock signal according to the capacitance of a capacitor, a voltage provided by a voltage source, and a current provided by a current source, and a random number generator to provide a random number to modulate the capacitance for jittering the frequency of the clock signal. This frequency jitter circuit does not need any counter to vary the capacitance responsive to the clock signal or any second current or voltage source to jitter the frequency of the clock signal.

In still another embodiment according to the present invention, a frequency jitter circuit includes an oscillator to generate a clock signal according to the capacitance of a capacitor, a voltage provided by a voltage source, a current provided by a current source, and a counter to provide a count value responsive to the clock signal to modulate the capacitance for jittering the frequency of the clock signal. This frequency jitter circuit does not need any second current or voltage source to jitter the frequency of the clock signal.

In a further embodiment according to the present invention, a frequency jitter method generates a clock signal according to a capacitance, a voltage and a current, and provides a random number to modulate the capacitance, the voltage or the current for jittering the frequency of the clock signal.

In another further embodiment according to the present invention, a frequency jitter method generates a clock signal according to a capacitance, a first voltage and a first current, generates a count value responsive to the clock signal, and modulates the capacitance according to the count value for jittering the frequency of the clock signal.

### BRIEF DESCRIPTION OF THE DRAWINGS

These and other objectives, features and advantages of the present invention will become apparent to those skilled in the art upon consideration of the following description of the preferred embodiments of the present invention taken in conjunction with the accompanying drawings, in which:

FIG. 1 is a first embodiment of a frequency jitter circuit according to the present invention;

FIG. 2 is a first embodiment of the random number generator shown in FIG. 1;

FIG. 3 is a second embodiment of the random number generator shown in FIG. 1;

FIG. 4 is a first embodiment of the digital-to-analog current source shown in FIG. 1;

FIG. 5 is a second embodiment of the digital-to-analog current source shown in FIG. 1;

FIG. 6 is an embodiment of the oscillator shown in FIG. 1;

FIG. 7 is a second embodiment of a frequency jitter circuit according to the present invention;

FIG. 8 is a first embodiment of the digital-to-analog voltage source shown in FIG. 7;

FIG. 9 is a second embodiment of the digital-to-analog voltage source shown in FIG. 7;

FIG. 10 is a third embodiment of a frequency jitter circuit according to the present invention; and

FIG. 11 is a fourth embodiment of a frequency jitter circuit according to the present invention.

### DETAILED DESCRIPTION OF THE INVENTION

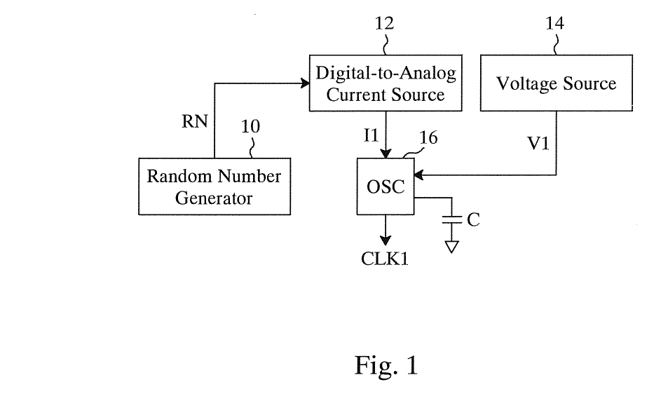

FIG. 1 is a first embodiment of a frequency jitter circuit according to the present invention, in which an oscillator 16 generates a clock signal CLK1 according to a current I1, a voltage V1 and the capacitance of a capacitor C with a frequency F=I1/(C×V1), and by modulating the current I1, the voltage V1 or the capacitance C, the frequency jitter circuit can jitter the frequency F. In this embodiment, the capacitance C has a constant value, a voltage source 14 provides the voltage V1 which has a constant value, and a digital-to-analog current source 12 provides the current I1 which is modulated by a random number RN provided by a random number generator 10 for jittering the frequency F of the clock signal CLK1. This frequency jitter circuit does not need any counter to vary the current I1 responsive to the clock signal CLK1, or any second current source to provide a variable current I1.

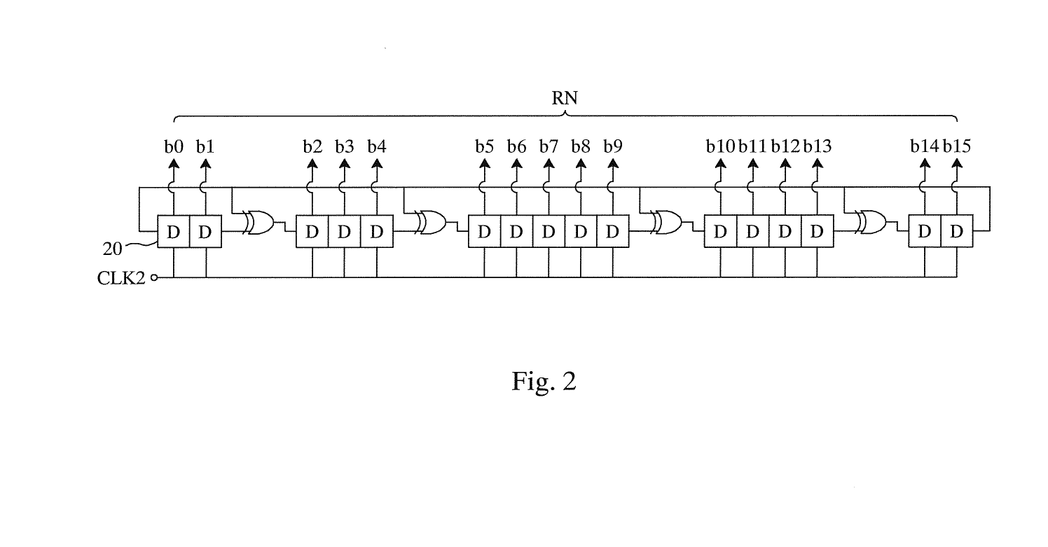

FIG. 2 is a first embodiment of the random number generator 10 shown in FIG. 1, which is a pseudo random number generator including sixteen serially connected D flip-flops 20, each outputting a one-bit signal b0-b15, to establish the random number RN. Thus, in this embodiment, the random number generator 10 provides a 16 bit random number RN.

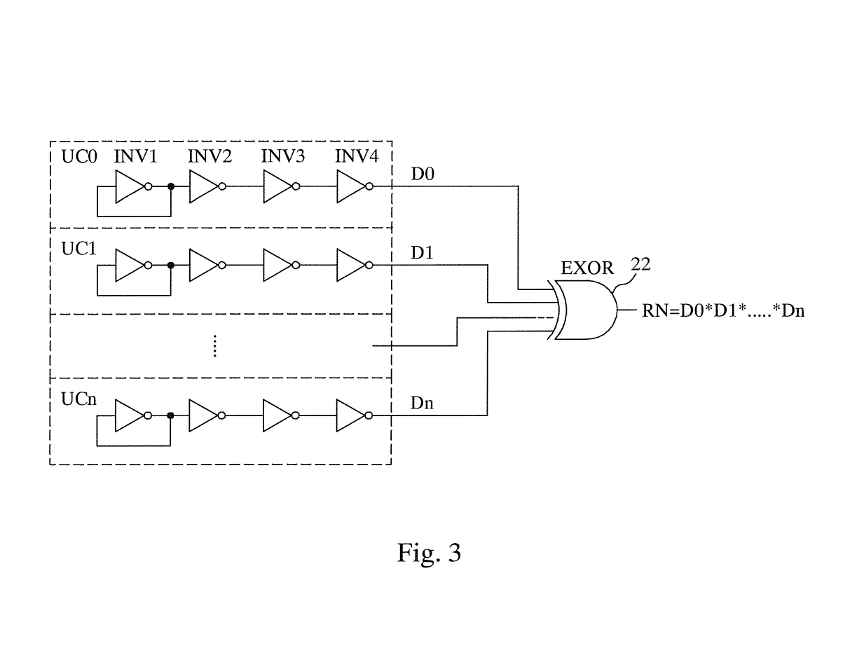

FIG. 3 is a second embodiment of the random number generator 10 shown in FIG. 1, which is a true random number generator including a plurality of circuits UC0-UCn, each established by a string of serially connected inverters, to generate signals D0-Dn, respectively, and an exclusive-OR gate 22 to generate a 1 bit random number RN according to the signals D0-Dn. By increasing the circuit shown in FIG. 3, the number of bits of the random number RN can be increased.

There are various schemes of random number generators. While only two popular ones among them are illustrated in the above embodiments, it is appreciated that the random number generators of other schemes may be useful to establish a frequency jitter circuit according to the present invention.

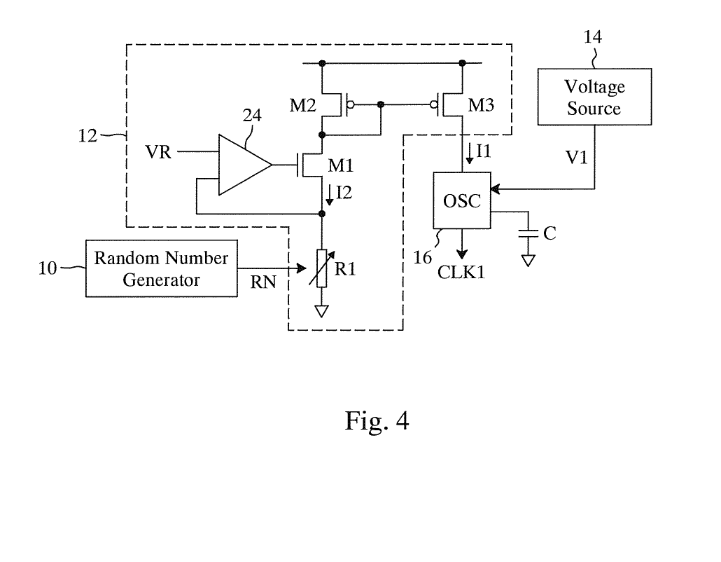

FIG. 4 is a first embodiment of the digital-to-analog current source 12 shown in FIG. 1, which includes an operational amplifier 24 having two inputs to receive a voltage VR and be connected to a variable resistor R1, respectively, and an output to control a transistor M1 connected between the variable resistor R1 and a current mirror established by two transistors M2 and m3. By virtual short between the tow inputs of the operational amplifier 24, the voltage VR is applied to the variable resistor R1 to establish a current I2 which is mirrored by the current mirror to generate the current I1. In this embodiment, the random number RN modulates the resistance of the variable resistor R1 to vary the current I2 and thus modulates the current I1 to thereby jitter the frequency F of the clock signal CLK1.

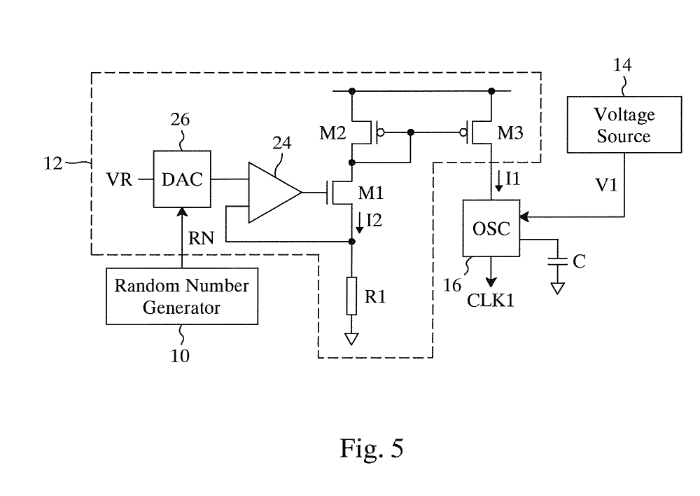

FIG. 5 is a second embodiment of the digital-to-analog current source 12 shown in FIG. 1, which is similar to the circuit of FIG. 4 but uses the random number RN to modulate the voltage VR instead by a DAC 26, to vary the current I2 to modulate the current I1 for jittering the frequency F of the clock signal CLK1.

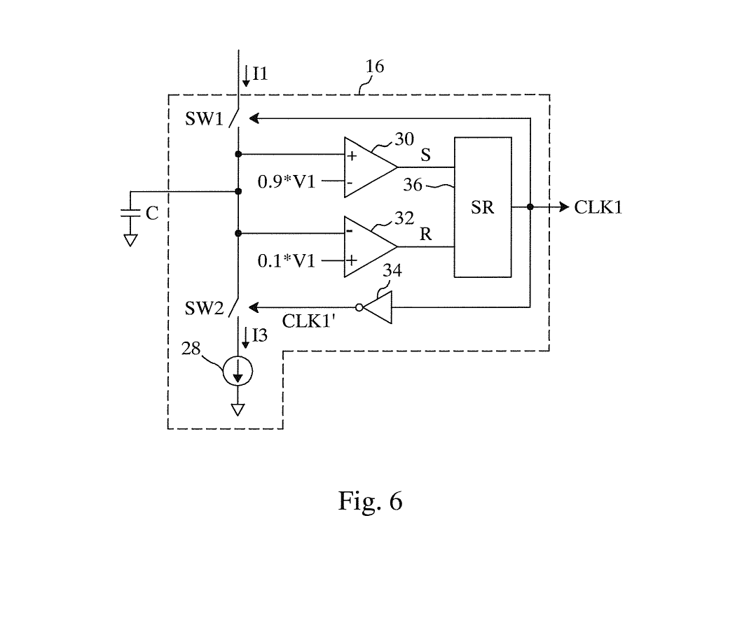

FIG. 6 is an embodiment of the oscillator 16 shown in FIG. 1, in which a switch SW1 is connected to the capacitor C and clocked by the clock signal CLK1 to charge the capacitor C by the current I1, a switch SW2 is connected between the capacitor C and a current source 28 and clocked by a signal CLK1′ produced by inverting the clock signal CLK1 by an inverter 34 to discharge the capacitor C by a current I3 provided by the current source 28, two comparators 30 and 32 compare the voltage on the capacitor C with two voltages 0.9V1 and 0.1V1 to assert a setting signal S and a resetting signal R, respectively, and an SR latch 36 generates the clock signal CLK1 responsive to the setting signal S and the resetting signal R. When the voltage on the capacitor C is larger than 0.9V1, the setting signal S is high to set the SR latch 36. When the voltage on the capacitor C is less than 0.1V1, the resetting signal R is high to reset the SR latch 36.

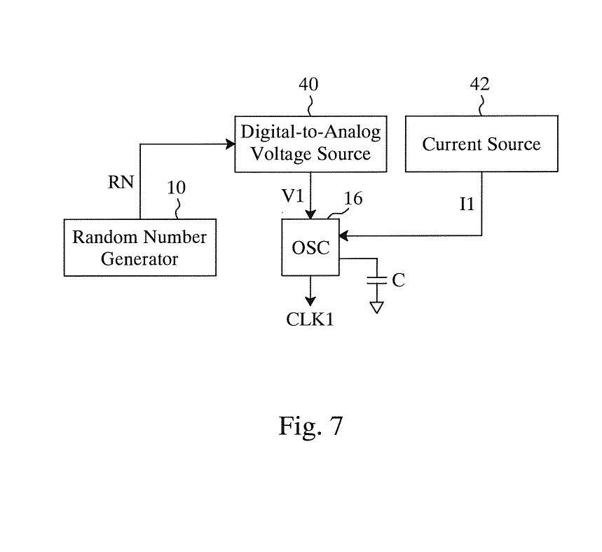

FIG. 7 is a second embodiment of the frequency jitter circuit according to the present invention, in which a current source 42 provides the current I1 which has a constant value, and the random number RN generated by the random number generator 10 is provided to a digital-to-analog voltage source 40 to modulate the voltage V1 for jittering the frequency F of the clock signal CLK1. This frequency jitter circuit does not need any counter to vary the voltage V1 responsive to the clock signal CLK1, or any second voltage source to provide a variable voltage V1.

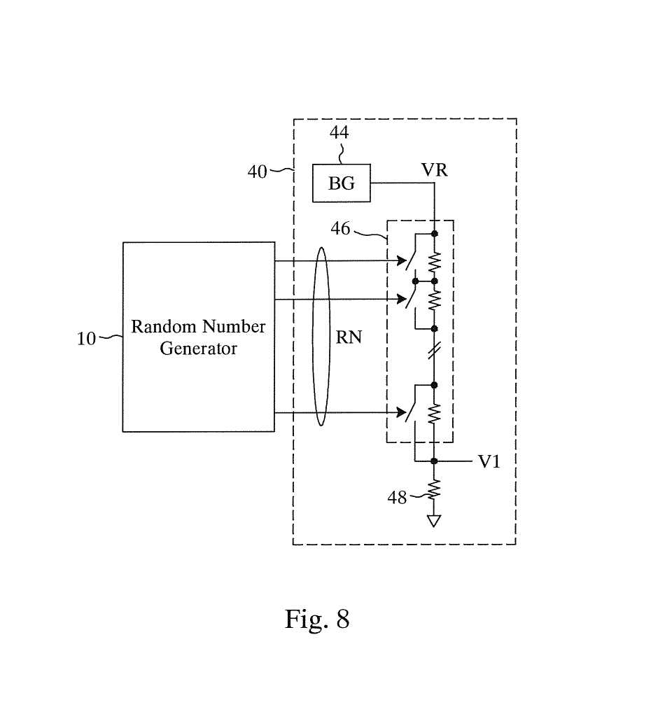

FIG. 8 is a first embodiment of the digital-to-analog voltage source 40 shown in FIG. 7, which includes a bandgap reference generator 44 to provide a voltage VR, and a variable resistor 46 and a resistor 48 connected in series to the bandgap reference generator 44 to divide the voltage VR to generate the voltage V1, with the random number RN to modulate the resistance of the variable resistor 46 and thereby the voltage V1.

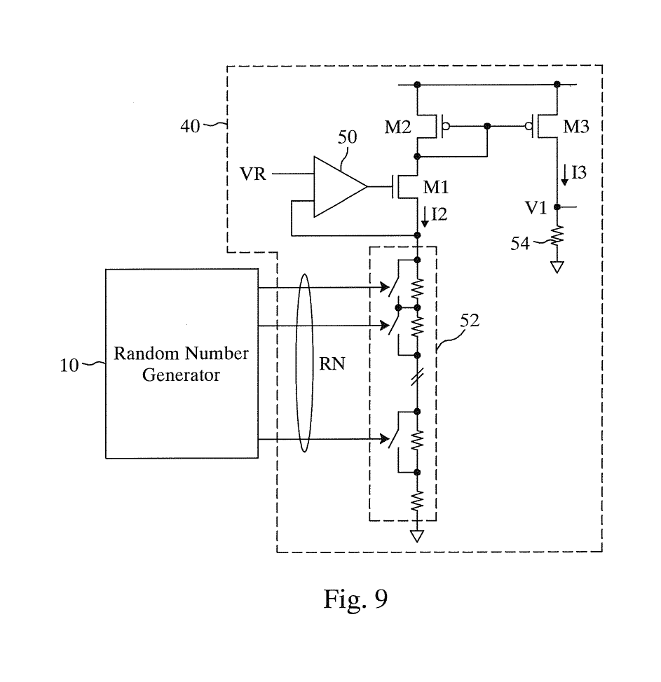

FIG. 9 is a second embodiment of the digital-to-analog voltage source 40 shown in FIG. 7, which includes an operational amplifier 50 having two inputs to receive a voltage VR and be connected to a variable resistor 52, respectively, and an output to control a transistor M1 connected between the variable resistor 52 and a current mirror established by two transistors M2 and m3. By virtual short between the tow inputs of the operational amplifier 50, the voltage VR is applied to the variable resistor 52 to establish a current I2 which is mirrored by the current mirror to generate a current I3 applied to a resistor 54 to generate the voltage V1. In this embodiment, the random number RN modulates the resistance of the variable resistor 52 to vary the current I2 and thus modulates the voltage V1 to thereby jitter the frequency F of the clock signal CLK1.

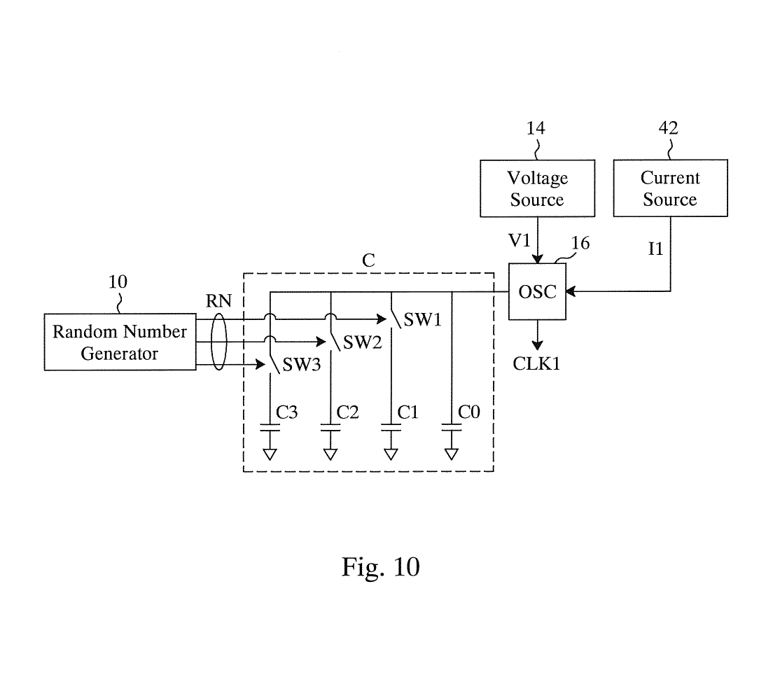

FIG. 10 is a third embodiment of the frequency jitter circuit according to the present invention, in which the voltage source 14 provides the voltage V1 which has a constant value, the current source 42 provides the current I1 which has a constant value, and the random number RN generated by the random number generator 10 is provided to modulate the capacitance C for jittering the frequency F of the clock signal CLK1. In this embodiment, the capacitor C includes four capacitor members C0-C3 connected in parallel and three switches SW1-SW3 connected in series with the capacitor members C1-C3, respectively. By using the random number RN to control the switches SW1-SW3, the switched capacitor network establishing the capacitor C has the capacitance C modulated by the random number RN to jitter the frequency F of the clock signal CLK1. This frequency jitter circuit does not need any counter responsive to the clock signal CLK1 or any second current or voltage source.

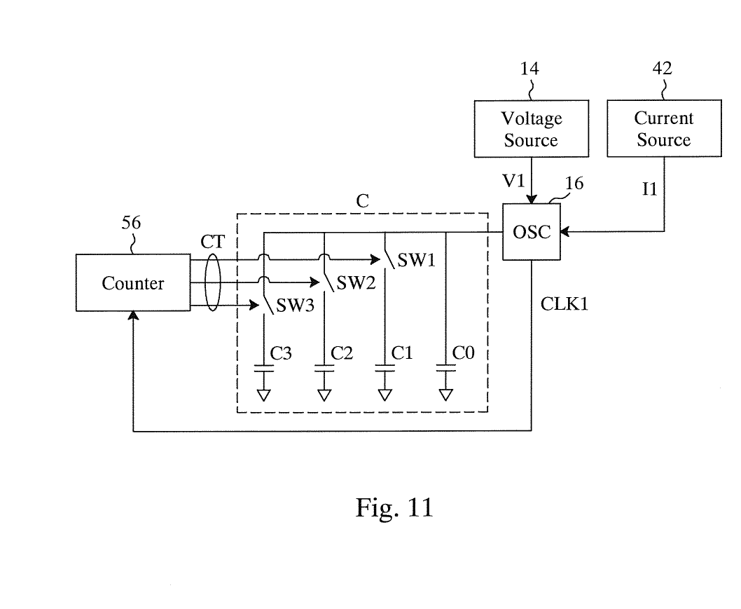

FIG. 11 is a fourth embodiment of the frequency jitter circuit according to the present invention, which is similar to the circuit of FIG. 10 but uses a counter 56 to modulate the capacitance C for jittering the frequency F of the clock signal CLK1. The counter 56 generates a count value CT responsive to the clock signal CLK1 generated by the oscillator 16 to control the switches SW1-SW3 within the switched capacitor network C. This frequency jitter circuit does not need any second current or voltage source or any DAC.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A frequency jitter circuit comprising:
a capacitor having a capacitance;
a voltage source providing a voltage;
a current source providing a current;
an oscillator connected to the capacitor, the voltage source and the current source, generating a clock signal according to the capacitance, the voltage and the current; and
a random number generator connected to the capacitor, providing a random number to modulate the capacitance for jittering a frequency of the clock signal.

2. The frequency jitter circuit of claim 1, wherein the capacitor comprises a switched capacitor network establishing the capacitance according to the random number.

3. A frequency jitter circuit comprising:
a capacitor having a capacitance;
a voltage source providing a voltage;
a current source providing a current;
an oscillator connected to the capacitor, the voltage source and the current source, generating a clock signal according to the capacitance, the voltage and the current; and
a counter connected to the capacitor and the oscillator, generating a count value responsive to the clock signal to modulate the capacitance for jittering a frequency of the clock signal.

4. The frequency jitter circuit of claim 3 wherein the capacitor comprises a switched capacitor network establishing the capacitance according to the count value.

5. A frequency jitter method comprising the steps of:
(A) generating a clock signal according to a capacitance, a voltage and a current; and
(B) modulating the capacitance by a random number for jittering a frequency of the clock signal.

6. A frequency jitter method comprising the steps of:
(A) generating a clock signal according to a capacitance, a voltage and a current;
(B) generating a count value responsive to the clock signal; and
(C) modulating the capacitance by the count value for jittering a frequency of the clock signal.
